(19) United States
(12) Patent Application Publication
(10) Pub. No.: US 2024/0021724 A1
(43) Pub. Date: Jan. 18, 2024

(54) GaN TRENCH MOSFET AND FABRICATION METHOD

(71) Applicant: SixPoint Materials, Inc., Buellton, CA (US)

(72) Inventor: Tadao Hashimoto, Santa Barbara, CA (US)

(21) Appl. No.: 18/222,411

(22) Filed: Jul. 14, 2023

Related U.S. Application Data
(60) Provisional application No. 63/389,363, filed on Jul. 14, 2022.

(51) Int. Cl. H01L 29/78; H01L 29/20; H01L 29/10; H01L 21/265; H01L 21/306; H01L 29/66

(52) U.S. Cl. CPC H01L 29/7813; H01L 29/2003; H01L 29/1095; H01L 21/26546; H01L 21/30621; H01L 29/66522; H01L 29/66734

(57) ABSTRACT

The present invention discloses a GaN trench MOSFET and its fabrication method. The GaN trench MOSFET of the current invention has an n-GaN region having both Mg and donor impurities below a trench bottom, extending to an n⁻-GaN drift layer. By utilizing multiple step ion implantations, an n-type GaN region is formed in Mg-doped p-GaN region below the trench bottom. Also, multiple steps of dry etching remove a portion of ion-implanted sidewall and enable formation of electron channel on the interface of p-GaN and oxide layer.

### CROSS REFERENCE TO RELATED APPLICATIONS

This patent application claims the benefit of priority to U.S. Provisional Patent Application 63/389,363 filed Jul. 14, 2022, with title “GaN TRENCH MOSFET AND FABRICATION METHOD” and inventor Tadao Hashimoto, which application is incorporated by reference in its entirety as if put forth in full below.

This application is related to the following patent applications:

PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.0129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

United States Utility Patent Application Ser. No. 60/973,602, filed on Sep. 19, 2007, by Tadao Hashimoto and Shuji Nakamura, entitled “GALLIUM NITRIDE BULK CRYSTALS AND THEIR GROWTH METHOD,” attorneys docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys docket number 30794.253-US-U1 (2007-774-2);

U.S. Utility patent application Ser. No. 12/392,960, filed on Feb. 25, 2009, by Tadao Hashimoto, Edward Letts, Masanori Ikari, entitled “METHOD FOR PRODUCING GROUP III-NITRIDE WAFERS AND GROUP III-NITRIDE WAFERS,” attorneys docket number SIXPOI-003US;

U.S. Utility patent application Ser. No. 12/455,760, filed on Jun. 4, 2009, by Edward Letts, Tadao Hashimoto, Masanori Ikari, entitled “METHODS FOR PRODUCING IMPROVED CRYSTALLINITY GROUP III-NITRIDE CRYSTALS FROM INITIAL GROUP III-NITRIDE SEED BY AMMONOTHERMAL GROWTH,” attorneys docket number SIXPOI-002US;

U.S. Utility patent application Ser. No. 12/455,683, filed on Jun. 4, 2009, by Tadao Hashimoto, Edward Letts, Masanori Ikari, entitled “HIGH-PRESSURE VESSEL FOR GROWING GROUP III NITRIDE CRYSTALS AND METHOD OF GROWING GROUP III NITRIDE CRYSTALS USING HIGH-PRESSURE VESSEL AND GROUP III NITRIDE CRYSTAL,” attorneys docket number SIXPOI-005US;

U.S. Utility patent application Ser. No. 12/455,181, filed on Jun. 12, 2009, by Tadao Hashimoto, Masanori Ikari, Edward Letts, entitled “METHOD FOR TESTING III-NITRIDE WAFERS AND III-NITRIDE WAFERS WITH TEST DATA,” attorneys docket number SIXPOI-001US;

U.S. Utility patent application Ser. No. 12/580,849, filed on Oct. 16, 2009, by Tadao Hashimoto, Masanori Ikari, Edward Letts, entitled “REACTOR DESIGN FOR GROWING GROUP III NITRIDE CRYSTALS AND METHOD OF GROWING GROUP III NITRIDE CRYSTALS,” attorneys docket number SIXPOI-004US;

U.S. Utility patent application Ser. No. 13/781,509, filed on Feb. 28, 2013, by Tadao Hashimoto, entitled “COMPOSITE SUBSTRATE OF GALLIUM NITRIDE AND METAL OXIDE,” attorneys docket number SIXPOI-012US;

U.S. Utility patent application Ser. No. 13/781,543, filed on Feb. 28, 2013, by Tadao Hashimoto, Edward Letts, Sierra Hoff entitled “A BISMUTH-DOPED SEMI-INSULATING GROUP III NITRIDE WAFER,” attorneys docket number SIXPOI-013US;

U.S. Utility patent application Ser. No. 13/833,443, filed on Mar. 15, 2013, by Tadao Hashimoto, Edward Letts, Sierra Hoff entitled “METHOD OF GROWING GROUP III NITRIDE CRYSTALS,” attorneys docket number SIXPOI-014U51;

U.S. Utility patent application Ser. No. 13/834,015, filed on Mar. 15, 2013, by Tadao Hashimoto, Edward Letts, Sierra Hoff entitled “METHOD OF GROWING GROUP III NITRIDE CRYSTALS,” attorneys docket number SIXPOI-014U52;

U.S. Utility patent application Ser. No. 13/834,871, filed on Mar. 15, 2013, by Tadao Hashimoto, Edward Letts, Sierra Hoff entitled “GROUP III NITRIDE WAFER AND ITS PRODUCTION METHOD,” attorneys docket number SIXPOI-015U51;

U.S. Utility patent application Ser. No. 13/835,636, filed on Mar. 15, 2013, by Tadao Hashimoto, Edward Letts, Sierra Hoff entitled “GROUP III NITRIDE WAFER AND ITS PRODUCTION METHOD,” attorneys docket number SIXPOI-015U52;

U.S. Utility patent application Ser. No. 13/798,530, filed on Mar. 13, 2013, by Tadao Hashimoto, entitled “GROUP III NITRIDE WAFERS AND FABRICATION METHOD AND TESTING METHOD,” attorneys docket number SIXPOI-016US;

U.S. Utility patent application Ser. No. 14/329,730, filed on Jul. 23, 2014, by Tadao Hashimoto, entitled “ELECTRONIC DEVICE USING GROUP III NITRIDE SEMICONDUCTOR AND ITS FABRICATION METHOD,” attorneys docket number SIXPOI-017US;
which applications are incorporated by reference herein in their entirety as if put forth in full below.

### BACKGROUND

### Field of the Invention

The invention relates to a semiconductor electronic device primarily used for high-power and/or high-frequency electric/electronic circuit. More specifically, the invention relates to transistors using group III nitride semiconductor.

### Description of the Existing Technology

(Note: This patent application refers several publications and patents as indicated with numbers within brackets, e.g., [x]. A list of these publications and patents can be found in the section entitled “References.”)

Gallium nitride (GaN) and its related group III nitride alloys are the key semiconductor material for various electronic devices such as power switching transistors. Despite the fact that the maximum performance of GaN theoretically predicted with Baliga's Figure of Merit (BFOM) exceeds that of silicon carbide (SiC) by ˜5-fold, difficulties of device fabrication as well as lack of low-cost and low-defect GaN substrates impedes development of GaN-based power switching transistors having their full potential.

Currently, the majority of GaN-based devices are fabricated using a group III nitride film grown heteroepitaxially on a heterogeneous substrates, such as silicon (Si), SiC and sapphire. As for GaN-based power devices, horizontal field effect transistors (FETs) fabricated on Si are commercialized. However, due to a thin current channel for horizontal devices, attainable power is limited. Also, due to poor material quality of GaN grown on Si, the device cannot withstand voltages higher than 1500V.

Vertical GaN FET fabricated on GaN substrate is the ideal device for high-power, high-reliability applications. Due to low dislocation density of homoepitaxial GaN, the device is expected to show low leakage current, high linearity, and high reliability. Despite the many efforts of fabricating vertical GaN metal-oxide-semiconductor FETs (MOSFETs), the device has not reached its full potential. This is primarily due to difficulties in forming a three-dimensional structure of p-GaN necessary to avoid the concentration of the electric field.

Some of these devices and performance issues inherent in them are discussed below in greater detail.

### SUMMARY OF THE INVENTION

The present invention discloses a GaN trench MOSFET and its fabrication method. The GaN trench MOSFET of the current invention has an n-GaN region having both Mg and donor impurities below a trench bottom and extending to an n⁻-GaN drift layer. By utilizing ion implantation, the n-type GaN region is formed in a Mg-doped p-GaN region and below the trench bottom of the MOSFET. Also, a dry etch removes a portion of ion-implanted trench sidewall and enables formation of an electron channel between an oxide layer and the Mg-doped p-GaN when forming a GaN trench MOSFET.

### BRIEF DESCRIPTION OF THE DRAWINGS

Referring now to the drawings in which like reference numbers represent corresponding parts throughout:

FIG. 1 illustrates an example of a conventional trench MOSFET formed using a semiconductor other than GaN.

In the figure each number represents the following:
101. n-type substrate
102. n⁻-type drift layer
103. p-type region
104. trench
104c. bottom edge of the trench
106. n-type source
107. electron channel
108. gate insulator
109. gate contact
110. body contact
111. source contact
112. drain contact
113. deep p-type region

Note: the numbers “105” and “205” were not used to help illustrate one difference that conventional trench MOSFETS have from the GaN trench MOSFET of this invention, which has a feature “5” as illustrated in FIGS. 3 and 4.

FIG. 2 illustrates an example of a conventional GaN trench MOSFET.

In the figure each number represents the following:
201. n-GaN substrate
202. n⁻-GaN drift layer
203. p-GaN region
204. trench
204c. bottom edge of the trench
206. n-GaN source
207. electron channel
208. gate insulator
209. gate contact
210. body contact
211. source contact
212. drain contact

FIG. 3 is one example of GaN trench MOSFET in this invention.

In the figure each number represents the following:
1. GaN substrate
2. n⁻-GaN drift layer
3. Mg-doped GaN layer
4. trench
4c. bottom edge of the trench
5. n-GaN region
6. n-GaN source
7. electron channel on p-GaN facet
8. gate insulator
9. gate contact
10. body contact
11. source contact
12. drain contact

FIG. 4 in its illustrations A through K shows one example of fabrication steps of the GaN trench MOSFET.
1. GaN substrate
2. n⁻-GaN drift layer
3. Mg-doped GaN layer
4. trench
4a. bottom of the trench
4b. sidewall of the trench
4c. bottom edge of the trench
5. n-GaN region
6. n-GaN source
6a. A mask for ion implantation for n-GaN source
7. electron channel on p-GaN facet
8. gate insulator
9. gate contact
10. body contact
11. source contact
12. drain contact

### DETAILED DESCRIPTION OF THE INVENTION

1. Further Discussion of Known Trench MOSFETs and Some of their Problems

A. Conventional MOSFETs Formed with Non-GaN Semiconductors Such as Si and SiC

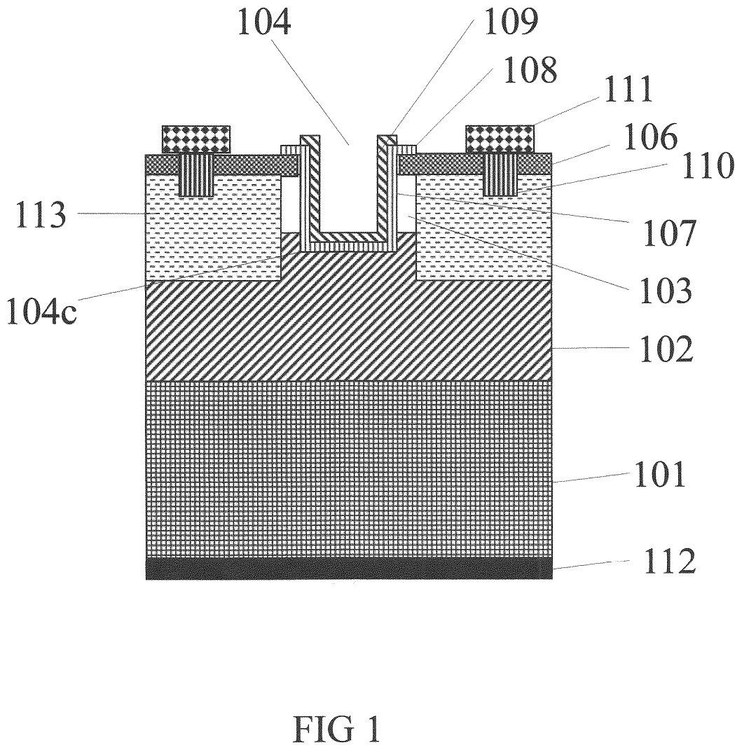

Various trench MOSFETs have been formed using Si or SiC semiconductors. Ref. 1 provides a review of trench MOSFETs, and FIG. 1 illustrates an example of a conventional trench MOSFET. A lightly doped (i.e., n⁻-type) drift layer 102 is grown on an n-type substrate 101. In operation, a high voltage is applied to this drift layer. Due to this high voltage, the carrier concentration of the drift layer is on the order of 10¹⁶ cm⁻³ or less to maximize the critical breakdown field of the layer. On top of the drift layer, p-type regions 103 and deep p-type regions 113 are formed using multiple ion implantation steps using electron acceptors. In the case of Si and SiC, p-type region can easily be formed in the drift layer 102 by ion implantation of acceptors. Then, n-type source 106 is formed by ion implantation of donor at the surface. A trench 104 is formed by etching the p-type material, followed by deposition of gate insulator (typically silicon dioxide) and gate metal. P body contacts 110, source contacts 111, and a drain contact 112 are formed through conventional semiconductor metallization steps. The p-body contacts 110 and the source contacts 111 are connected together so that the potential of p-type regions and deep p-type regions is pinned to the potential of the source.

One of the key technologies to achieve a high breakdown voltage device in a conventional MOSFET involves deep p-type regions. Without deep p-type regions, the electric field concentrates at the bottom edge of the trench and physical breakdown occurs at the bottom edge of the trench 104c, damaging the trench catastrophically. To avoid this problem, deep p-type regions extend towards the substrate 101. Since the type of breakdown occurring at the interface of the deep p-type region and the drift layer is avalanche breakdown rather than physical breakdown, breakdown does not cause catastrophic damage, i.e., the device can be used again after recovery from the avalanche breakdown.

B. Conventional MOSFETs Formed with GaN Semiconductor

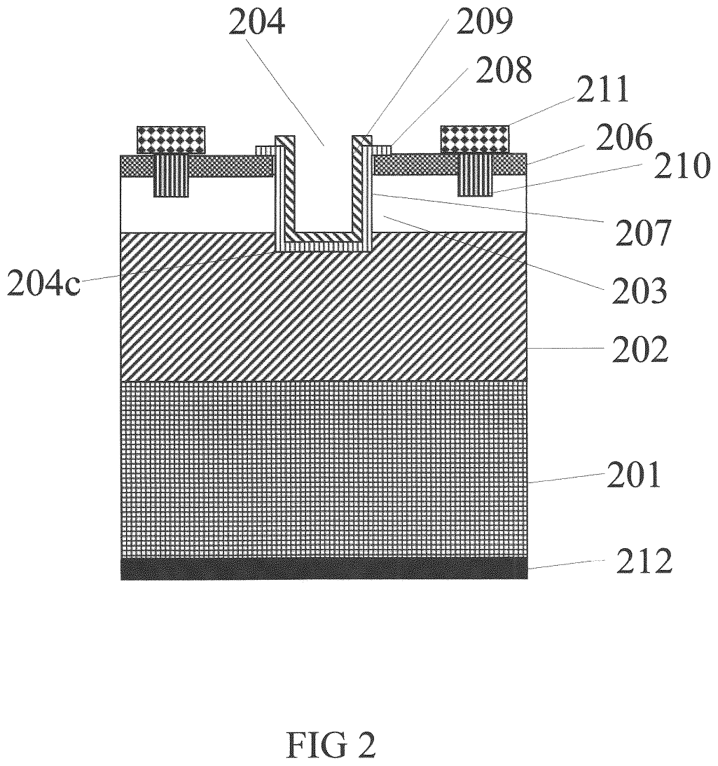

GaN is one of the wide bandgap semiconductors, and its material properties are superior to SiC. Thus, much research has been conducted to develop a GaN trench MOSFET. However, due to difficulties obtaining p-GaN by ion implantation of acceptors (typically Mg), the reported devices do not have the deep p-type region explained above, as Ref. [2] and [3] discuss. FIG. 2 is one example of a conventional GaN trench MOSFET. The GaN trench MOSFET is typically fabricated by growing n⁻-GaN drift layer 202 on the GaN substrate, then growing an acceptor-doped GaN layer on the drift layer 202 followed by a p-type activation anneal (typically at about 800° C.). A trench 204 is then formed by dry etching. The bottom of this etched trench extends into the n⁻-GaN drift layer 202 as is apparent from FIG. 2, which depicts both the gate insulator 208 and gate contact 209 extending beneath the interface of the p-GaN region and the n⁻-GaN drift layer 202. Since there are no deep p regions in the GaN trench MOSFET, device breakdown occurs physically at the bottom edge of the trench 204c, causing catastrophic failure of the device.

In an attempt to form deep p regions, p-type formation of GaN by ion plantation of acceptors (e.g., Mg) has been researched. Mg implantation followed by high-pressure (˜1 GPa), high-temperature anneal (>1000° C.) was reported to form p-GaN; however, high-pressure, high-temperature anneal is not practical for mass production [4],[5].

Another potential route to form deep p regions is to etch down the n⁻-GaN drift layer followed by selective regrowth of p-GaN. However, the regrowth interface typically has an accumulation of silicon impurities, causing high leakage current under high voltage bias.

2. Current Invention

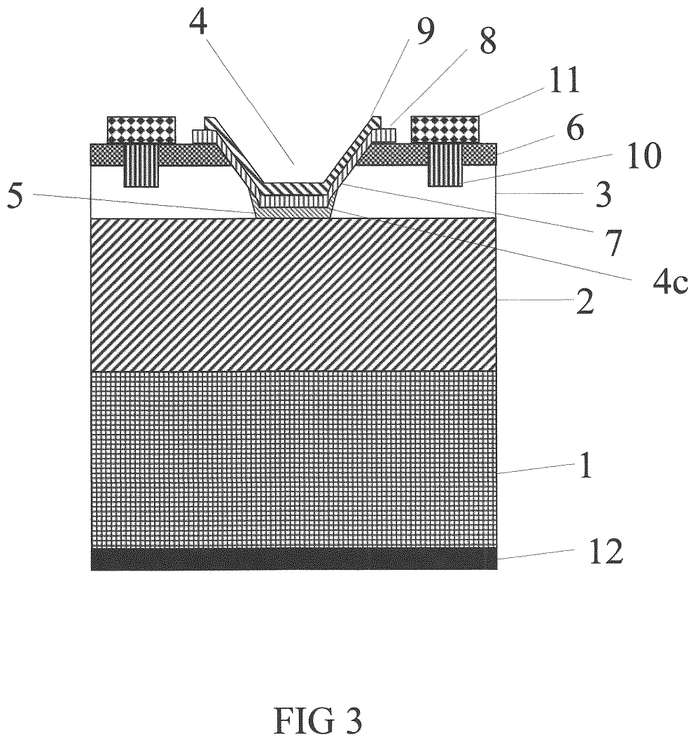

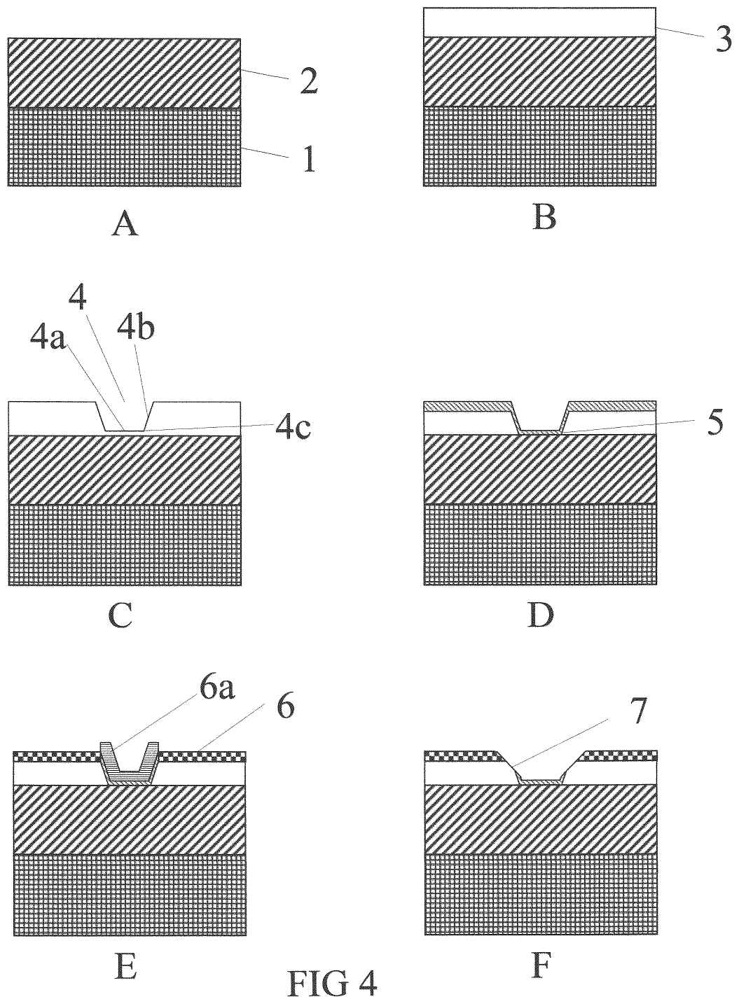

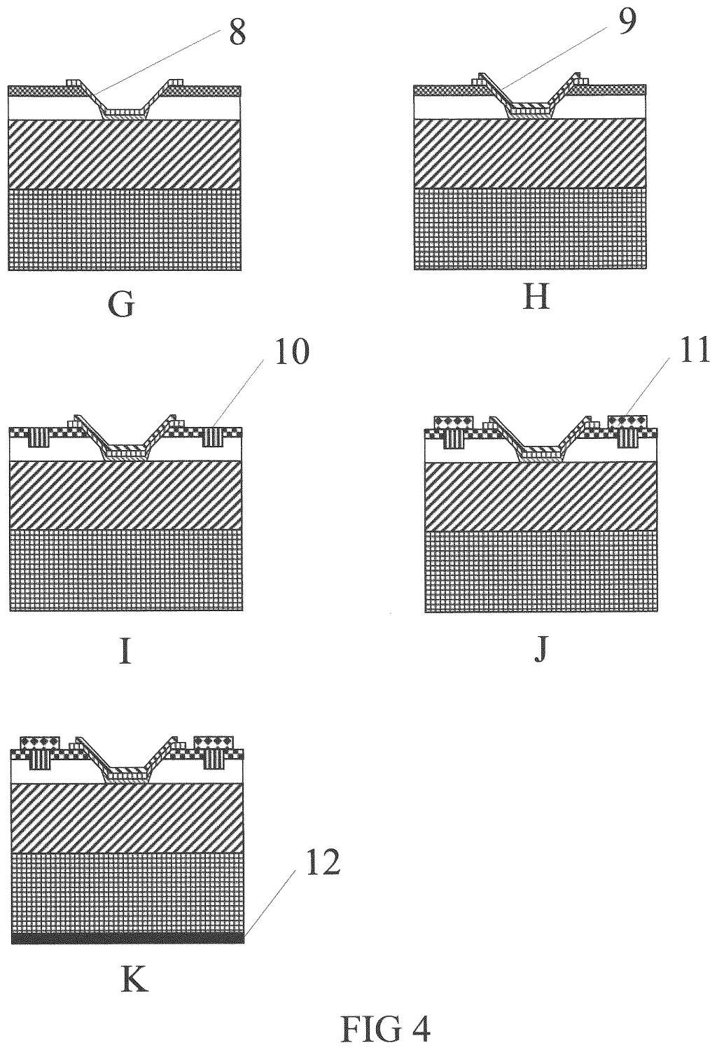

To provide a practical GaN trench MOSFET having deep p regions, this invention provides the novel structure and fabrication steps as explained below. FIG. 3 is an example of the GaN trench MOSFET in this invention. The device has an n⁻-GaN drift layer 2 grown on a GaN substrate 1. Similar to the conventional trench MOSFET, the electron concentration of n⁻-GaN is on the order of 10¹⁶ cm⁻³ or less, preferably less than 2×10 16 cm⁻³, and more preferably less than 8×10¹⁵ cm⁻³. The p-type Mg doped GaN layer 3 resides on the n⁻-GaN drift layer but is interrupted by the n-GaN region 5 under the trench 4. One of the key steps of this invention is the formation of the n-GaN region 5. The n-GaN region 5 is formed by ion implantation of donor into a portion of Mg doped GaN layer 3. The carrier concentration of the n-GaN region 5 is close to that of the n⁻-GaN drift layer, within +/−50% difference of the carrier concentration of the n⁻-GaN drift layer. It is preferably on the order of 10¹⁶ cm⁻³ or less.

As shown in FIG. 3, the final device has the n-GaN region 5 mostly under the trench extending vertically downward to the n⁻-GaN drift layer 2. The n-GaN region 5 also extends laterally from the sidewall of the trench so that tip of the n-GaN region 5 touches the electron channel on p-GaN facet 7 and collects electrons passing through the electron channel on p-GaN facet 7 beneath gate insulator. In this structure, the interface between the n⁻-GaN drift layer 2 and the p-GaN formed from the Mg-doped GaN layer 3 is closer to the substrate 1 than the interface between the n-GaN region 5 and the edge of the electron channel on p-GaN facet 7. Therefore, electric field concentration does not occur at the bottom edge of the trench 4c. Breakdown occurs at the interface between the p-GaN formed from the Mg-doped GaN layer 3 and the n⁻-GaN drift layer, allowing for avalanche breakdown and not physical breakdown.

To create the electron channel 7 on the facet of the p-GaN formed from the Mg-doped GaN layer 3, the p-GaN facet is formed by dry etching. The p-GaN facet is preferably a crystallographic plane selected from (101), (201), or (102) planes. The (101), (201), and (102) planes make angle of approximately 62°, 75°, and 43°, respectively. Since these crystallographic planes are stable planes, they are expected to create less surface state upon deposition of insulating layer. The details of the fabrication steps are explained below.

FIG. 4 provides an example of fabrication steps of the GaN trench MOSFET of this invention. The fabrication starts with growth of the n⁻-GaN drift layer 2 on n-GaN substrate 1 (FIG. 4A). Although n-GaN substrate produced by any method can be used, it is preferable to use a GaN substrate having low dislocation density. GaN substrates produced by the ammonothermal method typically have 2×10⁵ cm⁻² or less dislocation density, which is about one order of magnitude lower dislocation density than GaN substrates produced by vapor phase method. It is preferable to use GaN substrate with dislocation density lower than 5×10⁵ cm⁻³. The n⁻-GaN layer is preferably grown by metalorganic chemical vapor deposition (MOCVD) because MOCVD can grow a low impurity GaN layer at a practical growth rate (˜5 microns/hour).

After the drift layer growth, Mg-doped GaN layer 3 is grown. It is preferable to grow Mg-doped GaN layer 3 without interruption after finishing the growth of n⁻-GaN drift layer 2 to avoid accumulation of silicon impurities at the interface between the n⁻-GaN drift layer 2 and the Mg-doped GaN layer 3 (FIG. 4 B). After the growth, the wafer is annealed at about 800° C. to activate the Mg impurities. The activation annealing turns the Mg-doped GaN layer 3 into p-type GaN.

After growth, the wafer is taken out of the growth reactor and a trench 4 is formed by etching with an appropriate mask. Etching mask can be photoresist, a metal layer, or a dielectric layer. It is preferable to use dry etching because it can produce a trench with sidewalls closer to vertical angle. The trench 4 has a bottom 4a and sidewalls 4b (FIG. 4 C). It is important to stop etching prior to etching to the interface between the n⁻-GaN drift layer 2 and the p-GaN formed from Mg-doped GaN layer 3. Also, it is important to form the trench bottom 4a to be close enough to the interface between the n⁻-GaN drift layer 2 and the p-GaN formed from Mg-doped GaN layer 3 so that the successive ion implantation into the p-GaN at the bottom surface 4a of trench 4 that the implanted ion convert most or all of this region into n-type GaN. Practically, it is preferred to keep the thickness of this region less than 1 microns, preferably less than 0.5 microns, or more preferably equal to or about equal to 0.2 microns as measured from the bottom of the trench to the drift layer.

Then, the donor impurities are implanted into the wafer. Although any donor impurities such as Si, O, and Ge can be used, it is preferable to use Si because Si is the most common donor in GaN. The dose amount is set so that the region below the bottom of the trench turns into n-GaN having an electron concentration close to that of the n⁻-GaN drift layer, within +/−50% difference of the carrier concentration of the n⁻-GaN drift layer. As explained above, the electron concentration is on the order of 10¹⁶ cm⁻³ or less, preferably less than 2×10¹⁶ cm⁻³, and more preferably les than 8×10¹⁵ cm⁻³. In this way, the region below the bottom of the trench is turned into n-type. (n-GaN region 5). Also, all regions near the exposed surfaces (trench sidewalls and n-GaN source regions) become n-type as shown in FIG. 4 D.

To increase the electron concentration and form the n-GaN source 6, additional donor implantation is preferably conducted by covering the trench with a mask 6a (FIG. 4 E) and then implanting the n-GaN source region 6 with additional donor. After the ion implantation, the mask 6a is removed.

To remove the n-GaN region formed at the surface of the sidewall and expose the p-GaN facet, a dry etch is conducted to remove the n-GaN region as shown in FIG. 4 F. To expose the p-GaN facet with partially maintaining n-GaN region below the bottom of the trench, the facet angle is carefully controlled. The detailed technique of controlling the angle is well known and is outlined in reference [6], which is incorporated by reference in its entirety. It is preferable to use a dry etching with photoresist mask to control the facet angle accurately. The top surface of the p-GaN facet will become electron channel 7.

Once the electron channel 7 is exposed, a gate insulator 8 is deposited as shown in FIG. 4 G. The patterning of the gate insulator can be achieved with a conventional semiconductor process. The material of the gate insulator is selected to reduce and preferably minimize the interface energy state, as is well-known in the art. It is preferable to use aluminum nitride, aluminum oxide, silicon nitride, or silicon dioxide although other exotic insulator material can be used if the surface state is reduced or minimized.

Gate contact 9 is deposited on the gate insulator 8 with a conventional semiconductor process (FIG. 4 H) followed by formation of p body contact 10 (FIG. 4 I), source contact 11 (FIG. 4 J), and drain contact 12 (FIG. 4 K).

### Example 1

Bulk crystals of GaN are grown with the near equilibrium ammonothermal method. A bulk crystal of GaN is grown on a c-plane GaN seed crystal. A c-plane 2″ GaN substrate having dislocation density of 2×10⁵ cm⁻², carrier concentration of 2×10¹⁸ cm⁻³, miscut orientation of 0.04 degree toward m-direction, and miscut orientation of 0.00 degree toward a-direction is produced by slicing the bulk GaN followed by grinding, lapping, polishing and chemical mechanical polishing.

A 10 micron-thick n⁻GaN drift layer and 0.9 micron-thick Mg-doped GaN layer are grown by MOCVD using trimethylgallium and ammonia. To dope the n⁻GaN drift layer slightly with Si, SiH₄ gas diluted with hydrogen is introduced during drift layer growth. The electron concentration of the n⁻GaN drift layer is 1×10¹⁶ cm⁻³. To grow the Mg-doped GaN layer, bis(cyclopentadienyl) magnesium (Cp₂Mg) carried by hydrogen gas is introduced into the MOCVD reactor. After the MOCVD growth, the wafer is taken out of the MOCVD reactor and annealed at 800° C. in nitrogen gas to activate the Mg dopant. Through this activation anneal, the Mg-doped GaN layer turns into p-GaN layer. The Mg concentration of the p-GaN layer is 2×10¹⁸ cm⁻³.

The wafer goes through a photolithography step followed by dry etching to form trenches on the wafer. Inductively coupled plasma (ICP) etching with Cl₂ gas using photoresist mask is conducted to obtain trenches having virtually vertical sidewalls, as known in the art. Looking at the wafer from the top, the trenches are hexagonally shaped with point-to-point dimension of approximately 1 microns. The sides of the trenches are aligned to m-planes of GaN. The depth of the trench is approximately 0.7 microns. The dry etching ends prior to exposing the n⁻GaN drift layer 2, leaving approximately a 0.2 micron-thick p-GaN region between the bottom of the trench and the interface between the n⁻GaN drift layer and the p-GaN layer.

Ion implantation of Si is performed without masking the wafer to convert the p-GaN region between the bottom of the trench and the interface between the n⁻GaN drift layer and the p-GaN layer. After the ion implantation, the wafer is annealed at 800° C. in nitrogen gas to activate the Si. The resulting electron concentration in the region is approximately 1×10¹⁶ cm⁻³, which matches the electron concentration of the n⁻GaN drift layer. It is preferable to have the electron concentration in the region to be within +/−50% difference of the carrier concentration of the n⁻GaN drift layer.

To increase the electron concentration in the source region, additional Si implantation is conducted with covering the trench bottoms and trench walls with a dielectric mask. The electron concentration of the n-GaN source region is approximately 5×10 18 cm⁻³. After the implantation, the dielectric mask is removed by e.g., wet etching.

To expose p-GaN facet that will form the electron channel, inductively-coupled plasma (ICP) etching with photoresist mask is performed. In this case, by using different photoresist thickness and material, (101) plane of p-GaN is exposed. The angle of the facet is about 62° to the basal (002) plane. The details of controlling the facet angle are outlined in Ref. [6]. In this way the portion of n-GaN on the sidewalls of the trenches is removed, exposing p-GaN facet. Then, alumina layer and SiO₂ layer are each deposited as gate dielectric, followed by deposition of a Ti/Al gate contact. The conventional semiconductor process is used for the patterning of the gate contact.

Similarly, by using the conventional semiconductor process, body contacts are made by dry etching of the n-GaN source followed by patterned deposition of Ni/Au to p-GaN layer. Finally, source contact of Ti/Al and drain contact of Ti/Al are formed to complete the GaN MOSFET structure.

The completed GaN MOSFET structure has a deep p-region. The breakdown voltage is over 1000 V and the breakdown occurs in a region other than the trench because the bottom of the trench is farther from the substrate than the interface between the p-GaN and the n⁻-GaN drift layer. The inventive device is not catastrophically (physically) damaged even after the breakdown because the breakdown occurring at the interface between p-GaN and the n⁻-GaN drift layer is avalanche mode, not physically destructive mode. By avoiding the physical breakdown occurring under the trench as occurs in the conventional device of FIG. 2, the inventive device can be more reliable. Also, the structure of the inventive device can avoid concentration of the electric field at the edge of the trench bottom, likely resulting in a higher breakdown voltage than the conventional device.

Possible Modifications

Although the preferred embodiment describes usage of GaN substrate produced by the ammonothermal method, GaN substrates produced by other methods such as HVPE can also be used.

Although the preferred embodiment describes usage of MOCVD as layer growth method, other methods such as HVPE, and molecular beam epitaxy can also be used.

Although the preferred embodiment describes ICP etching to form trenches, other dry etching method such as reactive ion etching (RIE) can also be used.

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

### REFERENCES

The following references are incorporated by reference herein:
[1] R. K. Williams, et al., “The Trench Power MOSFET: Part I—History, Technology, and Prospects,” IEEE Transactions on Electron Devices Vol. 64 (2017) 674.
[2] T. Oka, et al., “1.8 mΩ·cm² vertical GaN-based trench metal-oxide-semiconductor field-effect transistors on a free-standing GaN substrate for 1.2-kV-class operation,” Applied Physics Express 8 (2015) 054101.
[3] R. Li, et al., “600 V/1.7 Normally-Off GaN Vertical Trench Metal-Oxide-Semiconductor Field-Effect Transistor,” IEEE Electron Devices 37 (2016) 1466.
[4] H. Sakurai, et al., “Highly effective activation of Mg-implanted p-type GaN by ultra-high-pressure annealilng,” Appl. Phys. Lett. 115 (2019) 142104.
[5] A. Uedono, et al., “Effects of ultra-high-pressure annealing on characteristics of vacancies in Mg-implanted GaN studies using a monoenergetic positron beam,” Sci. Rep. 10 (2020) 17349. https://doi.org/10.1038/s41598-020-74362-9.
[6] H. Hahn, et al., “Influence of mask material and process parameters on etch angle in a chlorine-based GaN dry etch,” J. Vac. Sci. Technol. A30 (2012) 051302.

Each of the references above is incorporated by reference in its entirety as if put forth in full herein, and particularly with respect to description of methods of making trench GaN MOSFETs, activating Mg-implanted p-type GaN, and making angled wall etches by selection of mask material and process parameters.

What is claimed is:

1. A GaN trench MOSFET fabricated on an n-GaN substrate comprising
(a) a drift layer of n⁻-GaN sharing an interface with the n-GaN substrate,
(b) a p-type Mg-doped GaN layer sharing an interface with the drift layer;
(c) a trench having an angled surface of p-type Mg-doped GaN,
(d) an n-GaN region below a bottom of the trench,
(e) an n-GaN source above the Mg-doped GaN layer and outside of the trench, wherein the n-GaN region contains both Mg and a donor impurity.

2. The GaN trench MOSFET of claim 1, wherein the n-GaN region extends from the bottom of the trench to the drift layer.

3. The GaN trench MOSFET of claim 1, wherein the n-GaN region extends laterally beneath the trench and from the trench bottom so that the interface between the drift layer and the p-type Mg-doped GaN layer is closer to the substrate than an interface between the n-GaN region and the p-type Mg-doped GaN layer.

4. The GaN trench MOSFET of claim 1, wherein the electron concentration of the n-GaN region is within +/−50% difference of the electron concentration of the n⁻-GaN drift layer.

5. The GaN trench MOSFET of claim 2, wherein the electron concentration of the n-GaN region is within +/−50% difference of the electron concentration of the n⁻-GaN drift layer.

6. The GaN trench MOSFET of claim 1, wherein said angled surface of p-type Mg-doped GaN is a crystallographic plane selected from (101), (201), or (102) plane.

7. The GaN trench MOSFET of claim 6, wherein the trench has plural angled surfaces of p-type Mg-doped GaN, and each of said surfaces is a crystallographic plane individually selected from (101), (201), or (102) plane.

8. The GaN trench MOSFET of claim 1, wherein the trench is hexagonally shaped.

9. A method of fabricating a GaN trench MOSFET comprising:
(a) forming a trench in a p-type Mg-doped GaN layer of a medium which comprises an n⁻-GaN drift layer which is beneath the Mg-doped GaN layer and which is above a GaN substrate when the MOSFET is oriented vertically, wherein the trench has a bottom and sidewalls in the p-type Mg-doped GaN layer;
(b) converting a region of the p-type Mg-doped GaN layer between the bottom of the trench and the drift layer into n-type conduction by donor ion implantation;
(c) exposing angled surfaces of p-type Mg-doped GaN layer in the trench by partially etching the sidewalls; and
(d) forming a source region of n-GaN outside of the trench.

10. The method of claim 9, wherein the donor ion implantation is performed using Si ions.

11. The method of claim 9, wherein angles between the sidewalls and the n-GaN substrate are steeper than angles between the angled surfaces of the p-type Mg-doped GaN layer and the n-GaN substrate.

12. The method of claim 9, wherein the angled surfaces of p-type Mg-doped GaN layer are each a crystallographic plane selected from (101), (201), or (102) plane.

13. The method of claim 10, wherein the angled surfaces of p-type Mg-doped GaN layer are each a crystallographic plane selected from (101), (201), or (102) plane.

14. The method of fabricating a GaN trench MOSFET of claim 9, wherein an electron concentration of the n⁻-GaN drift layer is less than 2×10¹⁶ cm⁻³ and an electron concentration of the region of p-type Mg-doped GaN layer between the bottom of the trench and the drift layer is less than 2×10¹⁶ cm⁻³.

15. The method of fabricating a GaN trench MOSFET of claim 10, wherein an electron concentration of the n⁻-GaN drift layer is less than 2×10¹⁶ cm⁻³ and an electron concentration of the region of p-type Mg-doped GaN layer between the bottom of the trench and the drift layer is less than 2×10¹⁶ cm⁻³.

16. The method of fabricating a GaN trench MOSFET of claim 12, wherein an electron concentration of the n⁻-GaN drift layer is less than 2×10¹⁶ cm⁻³ and an electron concentration of the region of p-type Mg-doped GaN layer between the bottom of the trench and the drift layer is less than 2×10¹⁶ cm⁻³.

17. The method of fabricating a GaN trench MOSFET of claim 13, wherein an electron concentration of the n⁻-GaN drift layer is less than 2×10¹⁶ cm⁻³ and an electron concentration of the region of p-type Mg-doped GaN layer between the bottom of the trench and the drift layer is less than 2×10¹⁶ cm⁻³.

18. The method of claim 9, wherein the GaN substrate has a dislocation density of 2×10⁵ cm⁻² or less.

19. The method of claim 9, wherein the trench is hexagonally shaped.
